(19) United States
(12) Patent Application Publication
(10) Pub. No.: US 2002/0053706 A1
(43) Pub. Date: May 9, 2002

(54) Semiconductor device and signal processing system having SOI MOS transistor

(75) Inventors: Mu-kyeng Jung, Seoul (KR); Byung-sun Kim, Suwon-city (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 09/910,304

(22) Filed: Jul. 20, 2001

(30) Foreign Application Priority Data
Nov. 8, 2000 (KR) 2000-66212

(51) Int. Cl. H01L 27/01; H01L 29/76; H01L 29/94; H01L 27/12

(52) U.S. Cl. 257/369; 257/347; 257/371

(57) ABSTRACT

A semiconductor device and a signal processing system having a metal oxide semiconductor (MOS) transistor with a silicon-on-insulator (SOI) structure are provided. The semiconductor device and the signal processing system include a main MOS transistor and an assistance MOS transistor. The main MOS transistor includes a first gate interconnection for receiving an external signal, first source/drain regions of a first conductivity type, and a body. The assistance MOS transistor includes a second gate interconnection and second source/drain regions of a second conductivity type opposite to the first conductivity type. The assistance MOS transistor selectively floats or grounds the body according to the external signal. The first gate interconnection and the second gate interconnection are electrically connected to each other by an interconnection layer.

### BACKGROUND OF THE INVENTION

1. Field of the Invention

The present invention relates to a semiconductor device, and more particularly, to a semiconductor device having a metal oxide semiconductor (MOS) transistor having a silicon-on-insulator (SOI) structure.

2. Description of the Related Art

As the capacity of memory cells of integrated circuits (ICs) becomes larger, transistors used in the memory cells of the ICs become smaller. As a result, a SOI MOS transistor has been studied in the development of a high-speed circuit, such as a high-speed central processing unit (CPU), or a low power device. The SOI MOS transistor formed on a thin single crystalline silicon layer on an insulating substrate can be highly integrated on one substrate using fine processing of silicon. Due to small leakage current, the SOI MOS transistor has good subthreshold characteristics and a high current driving ability and can suppress a short channel effect. The parasitic capacitance of the SOI MOS transistor is smaller than the parasitic capacitance of a conventional transistor in which a single crystalline silicon substrate is used. Thus, the SOI MOS transistor is suitable for a high-speed operation.

FIG. 1 is a sectional view of a typical SOI MOS transistor. As shown in FIG. 1, a typical SOI MOS transistor includes a buried oxide layer 12 formed on a semiconductor substrate 10, a surface silicon layer 20 formed on the buried oxide layer 12 for forming source/drain regions 22 and a channel region 24, a gate dielectric layer 30 formed on the channel region 24, and a gate interconnection 40 formed on the gate dielectric layer 30.

Where the transistor shown in FIG. 1 is a NMOS transistor, the source/drain regions 22 are n⁺ impurity regions, and where the transistor is a PMOS transistor, the source/drain regions 22 are p⁺ impurity regions. The source/drain regions 22 are electrically connected to other devices (not shown).

Many problems occur in the SOI MOS transistor having the above structure as the size of the semiconductor device decreases. That is, a channel region or a body of the NMOS transistor or PMOS transistor are not electrically connected but floated. Therefore, holes which are generated during the operation of a NMOS device or generated by a particles are accumulated in the body of the NMOS transistor, and thus, the floating body effect causes unstable operation. In particular, dynamic leakage current, as a result of parasitic bipolar characteristics, causes a malfunction in a device operated at a high frequency.

A structure for connecting the body to an external bias to fix the potential of the channel region has been suggested as one method for preventing the floating body effect. Examples of the method for preventing the floating body effect include using a channel potential fixation structure having an H-gate body contact in which the gate interconnection is formed in an H-shape or a channel potential fixation structure having a T-gate body contact in which the gate interconnection is formed in a T-shape.

FIGS. 2A and 2B are plan layout diagrams of a SOI MOS transistor having an H-shape gate interconnection and a T-shape gate interconnection, respectively. Referring to FIG. 2A, an active region 50 is divided by an H-shape gate interconnection 52 into four regions formed of two source/drain regions 54 and two bodies 58. Also, a channel region 56 exists between the source/drain regions 54 on lower portions of the H-shape gate interconnection 52.

Referring to FIG. 2B, an active region 60 is divided by a T-shape gate interconnection 62 into three regions formed of two source/drain regions 64 and one body 68. Also, a channel region 66 exists between the source/drain regions 64 on lower portions of the T-shape gate interconnection 62.

A SOI MOS transistor having the structure shown in FIGS. 2A or 2B can prevent the floating body effect by connecting each of the bodies 58 and 68 to the external bias. However, when the channel potential is fixed by connecting the body to the bias, junction capacitance in the channel region dramatically increases, more than when the body is floated, and when the junction capacitance of the channel region increases, the processing speed of the transistor deceases.

### SUMMARY OF THE INVENTION

To solve the above problems, it is a first object of the present invention to provide a semiconductor device having a silicon-on-insulator (SOI) metal oxide semiconductor (MOS) transistor having a structure in which the floating body effect can be prevented and problems caused by fixing the potential of a channel can be effectively prevented.

It is a second object of the present invention to provide a semiconductor device which is capable of properly changing the potential of a body according to an on or off state of a SOI MOS transistor, reducing leakage current when the SOI MOS transistor is in an off state, and reducing junction capacitance of a channel region and increasing operation current when the SOI MOS transistor is in an on state.

It is a third object of the present invention to provide a signal processing system having the above semiconductor device for improving operational characteristics.

According to one aspect of the present invention, there is provided a semiconductor device comprising a main metal oxide semiconductor (MOS) transistor including a first gate interconnection for receiving an external signal, first source/drain regions of a first conductivity type, and a body. An assistance MOS transistor of the device includes a second gate interconnection and second source/drain regions of a second conductivity type, opposite to the first conductivity type, for selectively floating or grounding the body according to the external signal. An interconnection layer electrically connects the first gate interconnection and the second gate interconnection.

In one embodiment, at least part of the second source/drain regions contacts the body of the main MOS transistor.

The first gate interconnection can be formed of one of an H-shape gate interconnection, a T-shape gate interconnection, and an elongated gate interconnection.

The main MOS transistor and the assistance MOS transistor can be formed on one active region, and the plane of the active region can be rectangular or “dog-bone shaped”.

In one embodiment, the semiconductor device of the present invention further comprises at least one first gate contact region formed on the first gate interconnection and at least one second gate contact region formed on the second gate interconnection. The interconnection layer is a conductive layer formed between the first gate contact region and the second gate contact region. The interconnection layer can be formed on upper portions of the first gate interconnection and the second gate interconnection that do not overlap the first source/drain regions and the second source/drain regions. Alternatively, the interconnection layer is formed on upper portions of the first gate interconnection and the second gate interconnection that overlap an isolation region.

The main MOS transistor can also include a channel region formed on a lower portion of the first gate interconnection in the body, and the assistance MOS transistor can be connected to the body extended from the channel region.

The body can be grounded by the assistance NMOS transistor when the external signal input to the main MOS transistor is at an off voltage level, and the body can be floated by the assistance NMOS transistor when the external signal input to the main MOS transistor is at an on voltage level.

According to another aspect of the present invention, there is provided a semiconductor device comprising a main complementary MOS (CMOS) circuit comprising a first main MOS transistor and a second main MOS transistor coupled to each other in a complimentary configuration, and at least one assistance MOS transistor for selectively floating or grounding a channel region of at least one main MOS transistor selected from the first main MOS transistor and the second main MOS transistor according to an on or off state of the selected main MOS transistor.

The selected main MOS transistor includes a first gate interconnection for receiving an external signal, a first source/drain region, a body, and a first channel region formed in a lower portion of the first gate interconnection in the body and having a channel of a first conductivity type formed therein. The assistance MOS transistor includes a second gate interconnection electrically connected to the first gate interconnection, a second source/drain region, and a second channel region having a channel of a second conductivity type, opposite to the first conductivity type. At least part of the second source/drain region contacts the body extended from the first channel region.

In one embodiment, the assistance MOS transistor is in an on state when the selected main MOS transistor is in an off state, and the assistance MOS transistor is in an off state when the selected main MOS transistor is in an on state. The first channel region is grounded when the selected main MOS transistor is in an off state, and the first channel region is floated when the selected main MOS transistor is in an on state.

In order to achieve the third object, there is provided a signal processing system including a central processing unit (CPU), a memory device, and a bus for connecting the CPU to the memory device. The CPU includes a main complementary MOS (CMOS) circuit comprising a first main MOS transistor and a second main MOS transistor coupled to each other in a complimentary configuration, and at least one assistance MOS transistor for selectively floating or grounding a channel region of at least one main MOS transistor selected from the first main MOS transistor and the second main MOS transistor according to an on or off state of the selected main MOS transistor.

In the semiconductor device of the present invention, when the main MOS transistor is in an on state, the body of the main MOS transistor is grounded so that the leakage current in an off state is reduced. When the main MOS transistor is in an off state, the body of the main MOS transistor is floated so that the junction capacitance in the channel region of the main MOS transistor is reduced, and current can be increased during the operation of the main MOS transistor. The signal processing system having a semiconductor device with the above characteristics can improve operational characteristics.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a sectional view of a typical SOI MOS transistor.

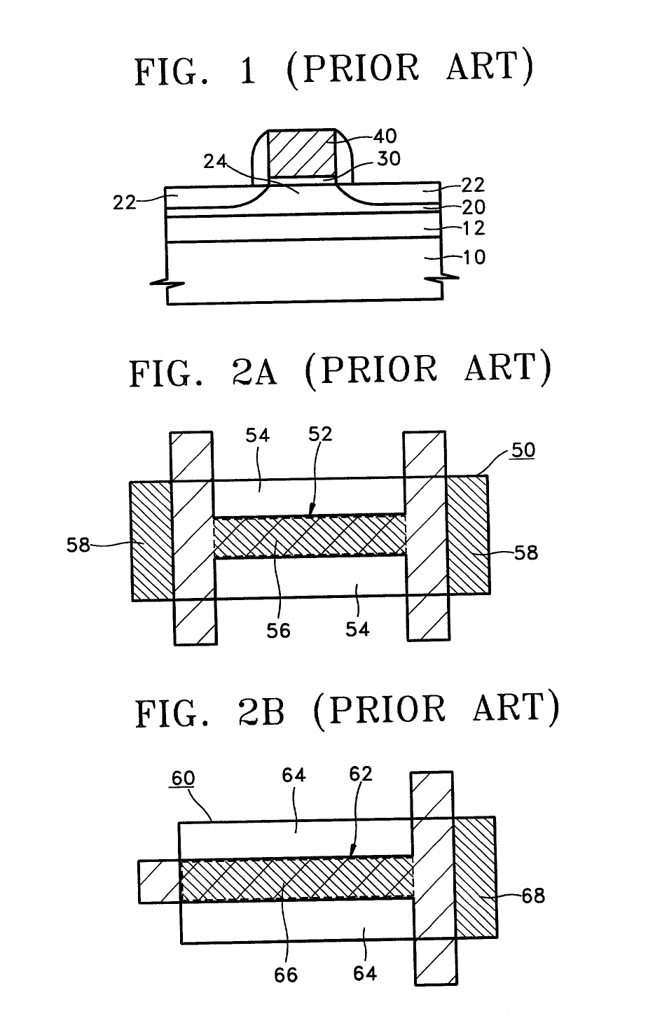

FIG. 2A is a plan layout diagram of a SOI MOS transistor of a conventional semiconductor device.

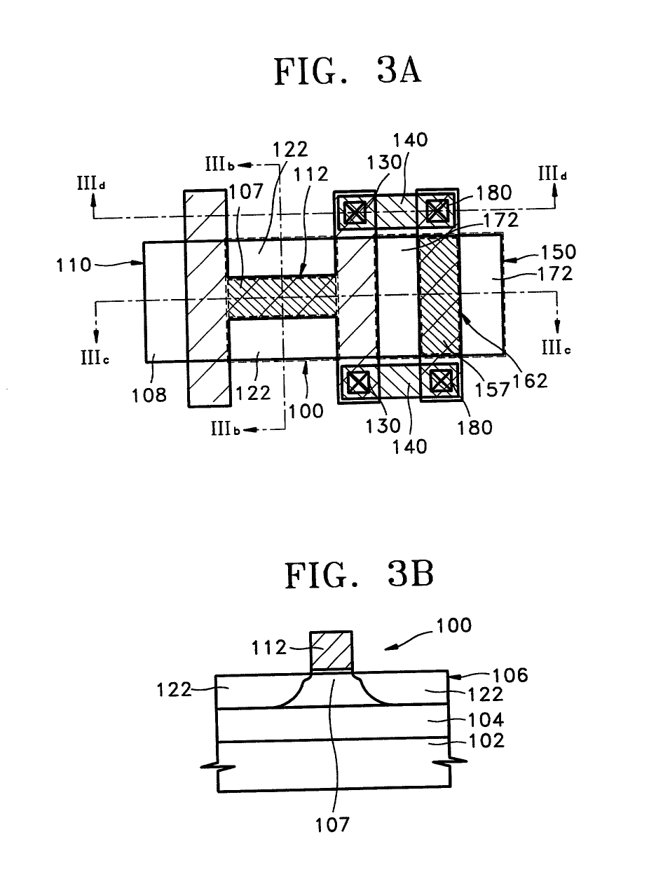

FIG. 2B is a plan layout diagram of a SOI MOS transistor of another conventional semiconductor device.

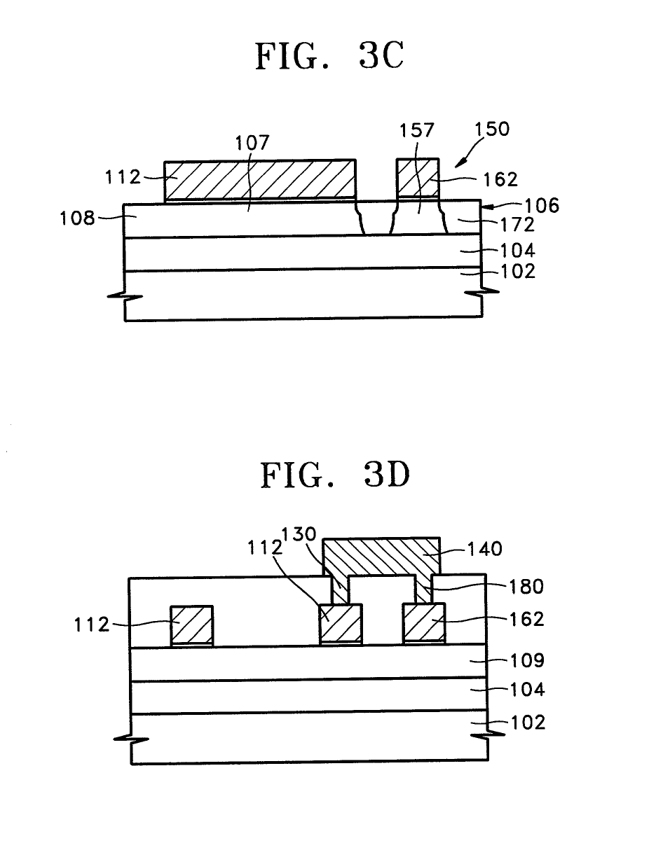

FIGS. 3A through 3D are diagrams of a semiconductor device according to a first embodiment of the present invention, where FIG. 3A is a plan layout diagram of the semiconductor device, FIG. 3B is a sectional view taken along line IIIb-IIIb of FIG. 3A, FIG. 3C is a sectional view taken along line IIIc-IIIc of FIG. 3A, and FIG. 3D is a sectional view taken along line IIId-IIId of FIG. 3A.

FIGS. 4A through 4D are diagrams of a semiconductor device according to a second embodiment of the present invention, where FIG. 4A is a plan layout diagram of the semiconductor device, FIG. 4B is a sectional view taken along line IVb-IVb of FIG. 4A, FIG. 4C is a sectional view taken along line IVc-IVc of FIG. 4A, and FIG. 4D is a sectional view taken along line IVd-IVd of FIG. 4A.

FIGS. 5A through 5D are diagrams of a semiconductor device according to a third embodiment of the present invention, where FIG. 5A is a plan layout diagram of the semiconductor device, FIG. 5B is a sectional view taken along line Vb-Vb of FIG. 5A, FIG. 5C is a sectional view taken along line Vc-Vc of FIG. 5A, and FIG. 5D is a sectional view taken along line Vd-Vd of FIG. 5A.

FIG. 6 is a block diagram of the semiconductor device according to an embodiment of the present invention.

FIG. 7 is a block diagram of a signal processing system according to an embodiment of the present invention.

### DETAILED DESCRIPTION OF PREFERRED EMBODIMENTS OF THE INVENTION

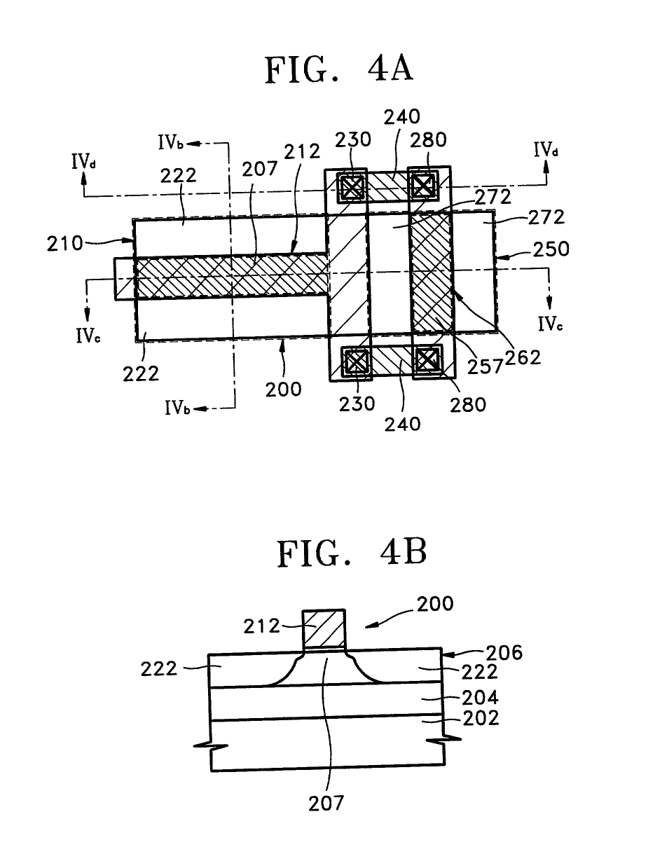

FIGS. 3A through 3D are diagrams of a semiconductor device according to a first embodiment of the present invention. FIG. 3A is a plan layout diagram of parts of the semiconductor device in which a main MOS transistor 100 has an H-shape gate interconnection 112, FIG. 3B is a sectional view taken along line IIIb-IIIb of FIG. 3A, FIG. 3C is a sectional view taken along line IIIc-IIIc of FIG. 3A, and FIG. 3D is a sectional view taken along line IIId-IIId of FIG. 3A.

The semiconductor device shown in FIGS. 3A through 3D is a SOI device comprising a semiconductor substrate 102 having a surface silicon layer 106 formed on a buried oxide layer 104. The semiconductor device according to the present invention includes a main MOS transistor 100 for receiving an external signal to perform a predetermined function, and an assistance MOS transistor 150 for selectively floating or grounding a body 108 or a first channel region 107 of the main MOS transistor 100 according to the external signal.

A rectangular active region 110 on the semiconductor substrate 102 is divided into five regions by the H-shape gate interconnection 112 of the main MOS transistor 100 and by an assistance gate interconnection 162 of the assistance MOS transistor 150. The five regions include the body 108, two first source/drain regions 122, and two second source/drain regions 172. The first source/drain regions 122 are part of the main MOS transistor 100, and the second source/drain regions 172 are part of the assistance MOS transistor 150. At least part of the second source/drain regions 172 contacts the body 108 of the main MOS transistor 100.

In the main MOS transistor 100, the first channel region 107 is formed on lower portions of the H-shape gate interconnection 112 between the two first source/drain regions 122 of the body 108. Similarly, in the assistance MOS transistor 150, a second channel region 157 is formed on lower portions of the assistance gate interconnection 162 between the two second source/drain regions 172.

The main MOS transistor 100 and the assistance MOS transistor 150 have channel regions of opposite conductivity types. That is, when the main MOS transistor 100 is a NMOS transistor, the assistance MOS transistor 150 is a PMOS transistor. Here, the first source/drain regions 122 are n⁺ impurity regions, and the second source/drain regions 172 are p⁺ impurity regions. On the contrary, when the main MOS transistor 100 is a PMOS transistor, the assistance MOS transistor 150 is a NMOS transistor. Here, the first source/drain regions 122 are p⁺ impurity regions, and the second source/drain regions 172 are n⁺ impurity regions.

The H-shape gate interconnection 112 of the main MOS transistor 100 and the assistance gate interconnection 162 of the assistance MOS transistor 150 are electrically connected to each other by an interconnection layer 140. The interconnection layer 140 is a conductive layer extended between a first gate contact region 130 on the H-shape gate interconnection 112 and a second gate contact region 180 on the assistance gate interconnection 162. The interconnection layer 140 may be formed of a plurality of conductive layers. For this purpose, a plurality of first gate contact regions 130 may be formed on the H-shape gate interconnection 112, and a plurality of second gate contact regions 180 may be formed on the assistance gate interconnection 162. In FIG. 3A, two first gate contact regions 130 are formed on the H-shape gate interconnection 112, two second gate contact regions 180 are formed on the assistance gate interconnection 162, and the interconnection layer 140 is formed of two conductive layers connecting the first gate contact regions 130 and the second gate contact regions 180. The conductive layer forming the interconnection layer 140 can be formed of a doped polysilicon or metal. One conductive layer or a plurality of conductive layers forming the interconnection layer 140 may be formed in any desired position. Resistance decreases more for an interconnection layer 140 formed of a plurality of conductive layers than for an interconnection layer 140 formed of one conductive layer. However, if the amount of resistance is not important, the interconnection layer 140 may be formed of one conductive layer.

The first gate contact regions 130 and the second gate contact regions 180 may be formed on the H-shape gate interconnection 112 and the assistance gate interconnection 162, preferably on a region which does not overlap the first and second source/drain regions 122 and 172, and more preferably, on an isolation region 109. Similarly, the interconnection layer 140 is preferably formed on a region which does not overlap the first and second source/drain regions 122 and 172, and more preferably formed on a region which overlaps the isolation region 109.

In the semiconductor device having the structure shown in FIGS. 3A through 3D, the body 108 extended from the first channel region 107 of the main MOS transistor 100 is connected to the assistance MOS transistor 150.

In the above semiconductor device, when an external signal at an off voltage level is input to the main MOS transistor 100 and the main MOS transistor 100 is turned off, the potential at the body 108 of the main MOS transistor 100 is increased by general floating characteristics. As a result, the assistance MOS transistor 150 turns on, and the potential of the body 108 then decreases. When a conventional SOI transistor is turned off, potential is increased by floating characteristics, and the transistor has bipolar characteristics. However, in the semiconductor device according to the present invention, the bipolar characteristics of the main MOS transistor 100 are nullified by the assistance MOS transistor 150, and the body 108 of the main MOS transistor 100 is grounded, and leakage current in an off state is reduced.

Also, when the external signal at an on voltage level is input to the main MOS transistor 100 and the main MOS transistor 100 is turned on, the assistance MOS transistor 150 is turned off, and the body 108 of the main MOS transistor 100 has floating characteristics. Thus, junction capacitance of the channel region 107 of the main MOS transistor 100 is maintained at a low level, and current is increased during the operation of the main MOS transistor 100.

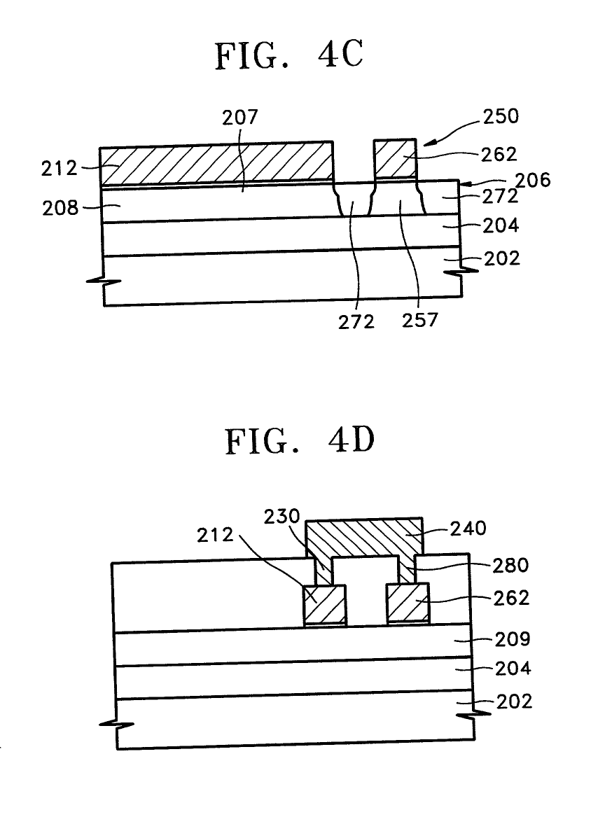

FIGS. 4A through 4D are diagrams illustrating the structure of a semiconductor device according to a second embodiment of the present invention. FIG. 4A is a plan layout diagram of parts of the semiconductor device in which a main MOS transistor 200 has a T-shape gate interconnection 212, FIG. 4B is a sectional view taken along line IVb-IVb of FIG. 4A, FIG. 4C is a sectional view taken along line IVc-IVc of FIG. 4A, and FIG. 4D is a sectional view taken along line IVd-IVd of FIG. 4A.

The semiconductor device shown in FIGS. 4A through 4D is a SOI device comprising a semiconductor substrate 202 having a surface silicon layer 206 formed on a buried oxide layer 204.

The semiconductor device according to the present invention includes a main MOS transistor 200 for receiving an external signal to perform a predetermined function, and an assistance MOS transistor 250 for selectively floating or grounding a body 208 or a first channel region 207 of the main MOS transistor 200 according to the external signal.

A rectangular active region 210 on the semiconductor substrate 202 is divided into four regions by the T-shape gate interconnection 212 of the main MOS transistor 200 and by an assistance gate interconnection 262 of the assistance MOS transistor 250. The four regions include two first source/drain regions 222, and two second source/drain regions 272. The first source/drain regions 222 are part of the main MOS transistor 200, and the second source/drain regions 272 are part of the assistance MOS transistor 250. At least part of the second source/drain regions 272 contacts the body 208 of the main MOS transistor 200.

In the main MOS transistor 200, the first channel region 207 is formed on lower portions of the T-shape gate interconnection 212 between the two first source/drain regions 222 of the body 208. Similarly, in the assistance MOS transistor 250, a second channel region 257 is formed on lower portions of the assistance gate interconnection 262 between the two second source/drain regions 272.

The channel regions of the main MOS transistor 200 and the assistance MOS transistor 250 have opposite conductivity type. That is, when the main MOS transistor 200 is a NMOS transistor, the assistance MOS transistor 250 is a PMOS transistor. Here, the first source/drain regions 222 are n⁺ impurity regions, and the second source/drain regions 272 are p⁺ impurity regions. On the contrary, when the main MOS transistor 200 is a PMOS transistor, the assistance MOS transistor 250 is a NMOS transistor. Here, the first source/drain regions 222 are p⁺ impurity regions, and the second source/drain regions 272 are n⁺ impurity regions.

The T-shape gate interconnection 212 of the main MOS transistor 200 and the assistance gate interconnection 262 of the assistance MOS transistor 250 are electrically connected to each other by an interconnection layer 240. The interconnection layer 240 is a conductive layer extended between a first gate contact region 230 on the T-shape gate interconnection 212 and a second gate contact region 280 on the assistance gate interconnection 262. The interconnection layer 240 may be formed of a plurality of conductive layers. For this purpose, a plurality of first gate contact regions 230 may be formed on the T-shape gate interconnection 212, and a plurality of second gate contact regions 280 may be formed on the assistance gate interconnection 262. In FIG. 4A, two first gate contact regions 230 are formed on the T-shape gate interconnection 212, two second gate contact regions 280 are formed on the assistance gate interconnection 262, and the interconnection layer 240 is formed of two conductive layers connecting the first gate contact regions 230 and the second gate contact regions 280, respectively.

Like the description of FIGS. 3A through 3D, one conductive layer or a plurality of conductive layers forming the interconnection layer 240 may be formed in a desired position. Also, the first gate contact region 230 and the second gate contact region 280 may be formed on the T-shape gate interconnection 212 and the assistance gate interconnection 262. In FIG. 4A through 4D, the interconnection layer 240 and the first and second gate contact regions 230 and 280 do not overlap the first and second source/drain regions 222 and 272, but do overlap an isolation region 209.

In the semiconductor device shown in FIGS. 4A through 4D, as in the case of FIGS. 3A through 3D, the body 208 extended from the first channel region 207 of the main MOS transistor 200 is connected to the assistance MOS transistor 250. Thus, when an external signal at an off voltage level is input to the main MOS transistor 200 and the main MOS transistor 200 is turned off, the potential at the body 208 of the main MOS transistor 200 is increased by general floating characteristics. As a result, the assistance MOS transistor 250 turns on, and the potential of the body 208 then decreases. Consequently, the bipolar characteristics of the main MOS transistor 200 are nullified by the assistance MOS transistor 250, the body 208 of the main MOS transistor 200 is grounded, and leakage current in an off state is reduced.

Also, when the external signal at an on voltage level is input to the main MOS transistor 200 and the main MOS transistor 200 is turned on, the assistance MOS transistor 250 is turned off, and the body 208 in the main MOS transistor 200 has floating characteristics. Thus, junction capacitance of the channel region 207 of the main MOS transistor 200 is maintained at a low level, and current is increased during the operation of the main MOS transistor 200.

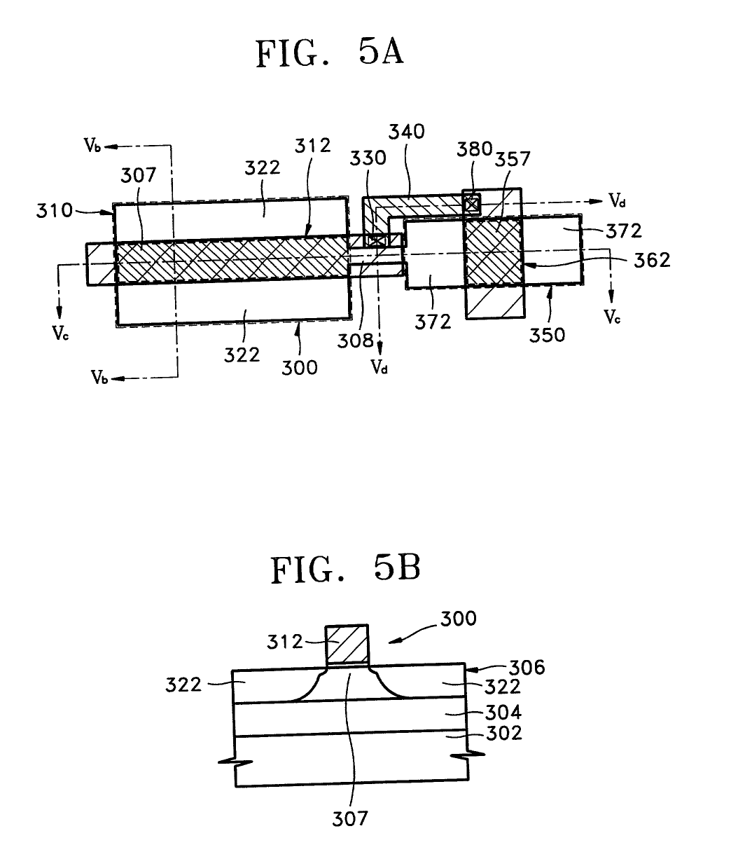

FIGS. 5A through 5D are diagrams of a semiconductor device according to a third embodiment of the present invention. FIG. 5A is a plan layout diagram of parts of the semiconductor device in which an active region 310 is formed in a dog bone shape and an elongated gate interconnection 312 is formed. FIG. 5B is a sectional view taken along line Vb-Vb of FIG. 5A, FIG. 5C is a sectional view taken along line Vc-Vc of FIG. 5A, and FIG. 5D is a sectional view taken along line Vd-Vd of FIG. 5A.

The semiconductor device shown in FIGS. 5A through 5D is a SOI device comprising a semiconductor substrate 302 having a surface silicon layer 306 formed on a buried oxide layer 304.

The semiconductor device according to the present invention includes a main MOS transistor 300 for receiving an external signal to perform a predetermined function, and an assistance MOS transistor 350 for selectively floating or grounding a body 308 or a first channel region 307 of the main MOS transistor 300 according to the external signal.

The elongated gate interconnection 312 of the main MOS transistor 300 and an assistance gate interconnection 362 of the assistance MOS transistor 350 are extended on the active region 310. First source/drain regions 322 are formed on both sides of the elongated gate interconnection 312 on the active region 310, and second source/drain regions 372 are formed on both sides of the assistance gate interconnection 362 on the active region 310. The first source/drain regions 322 are part of the main MOS transistor 300, and the second source/drain regions 372 are part of the assistance MOS transistor 350. At least part of the second source/drain regions 372 contacts the body 308 of the main MOS transistor 300.

In the main MOS transistor 300, the first channel region 307 is formed on lower portions of the elongated gate interconnection 312 between the two first source/drain regions 322 of the body 308. Similarly, in the assistance MOS transistor 350, a second channel region 357 is formed on lower portions of the assistance gate interconnection 362 between the two second source/drain regions 372.

The channel regions of the main MOS transistor 300 and the assistance MOS transistor 350 have opposite conductivity type. That is, when the main MOS transistor 300 is a NMOS transistor, the assistance MOS transistor 350 is a PMOS transistor. Here, the first source/drain regions 322 are n⁺ impurity regions, and the second source/drain regions 372 are p⁺ impurity regions. On the contrary, when the main MOS transistor 300 is a PMOS transistor, the assistance MOS transistor 350 is a NMOS transistor. Here, the first source/drain regions 322 are p⁺ impurity regions, and the second source/drain regions 372 are n⁺ impurity regions.

The elongated gate interconnection 312 of the main MOS transistor 300 and the assistance gate interconnection 362 of the assistance MOS transistor 350 are electrically connected to each other by an interconnection layer 340. The interconnection layer 340 is a conductive layer extended between a first gate contact region 330 on the elongated gate interconnection 312 and a second gate contact region 380 on the assistance gate interconnection 362. The interconnection layer 340 may be formed of a plurality of conductive layers. For this purpose, a plurality of first gate contact regions 330 may be formed on the elongated gate interconnection 312, and a plurality of second gate contact regions 380 may be formed on the assistance gate interconnection 362. In FIG. 5A, one first gate contact region 330 is formed on the elongated gate interconnection 312, one second gate contact region 380 is formed on the assistance gate interconnection 362, and the interconnection layer 340 is formed of one conductive layer connecting the first gate contact regions 330 and the second gate contact regions 380.

Like the description of FIGS. 3A through 3D, one conductive layer or a plurality of conductive layers forming the interconnection layer 340 may be formed in a desired position. Also, the first gate contact region 330 and the second gate contact region 380 may be formed in the elongated gate interconnection 312 and the assistance gate interconnection 362. In FIG. 5A through 5D, the interconnection layer 340 and the first and second gate contact regions 330 and 380 do not overlap the first and second source/drain regions 322 and 372, but do overlap an isolation region 309.

In the semiconductor device shown in FIGS. 5A through 5D, as in the cases of FIGS. 3A through 3D and FIGS. 4A through 4D, the body 308 extended from the first channel region 307 of the main MOS transistor 300 is connected to the assistance MOS transistor 350. Thus, when an external signal at an off voltage level is input to the main MOS transistor 300 and the main MOS transistor 300 is turned off, the potential at the body 308 of the main MOS transistor 300 is increased by general floating characteristics. As a result, the assistance MOS transistor 350 turns on, and the potential of the body 308 then decreases. Consequently, the bipolar characteristics of the main MOS transistor 300 are nullified by the assistance MOS transistor 350, and the body 308 of the main MOS transistor 300 is grounded, and leakage current in an off state is reduced.

Also, when the external signal at an on voltage level is input to the main MOS transistor 300 and the main MOS transistor 300 is turned on, the assistance MOS transistor 350 is turned off, and the body 308 of the main MOS transistor 300 has floating characteristics. Thus, junction capacitance in the channel region 307 of the main MOS transistor 300 is maintained at a low level, and current is increased during the operation of the main MOS transistor 300.

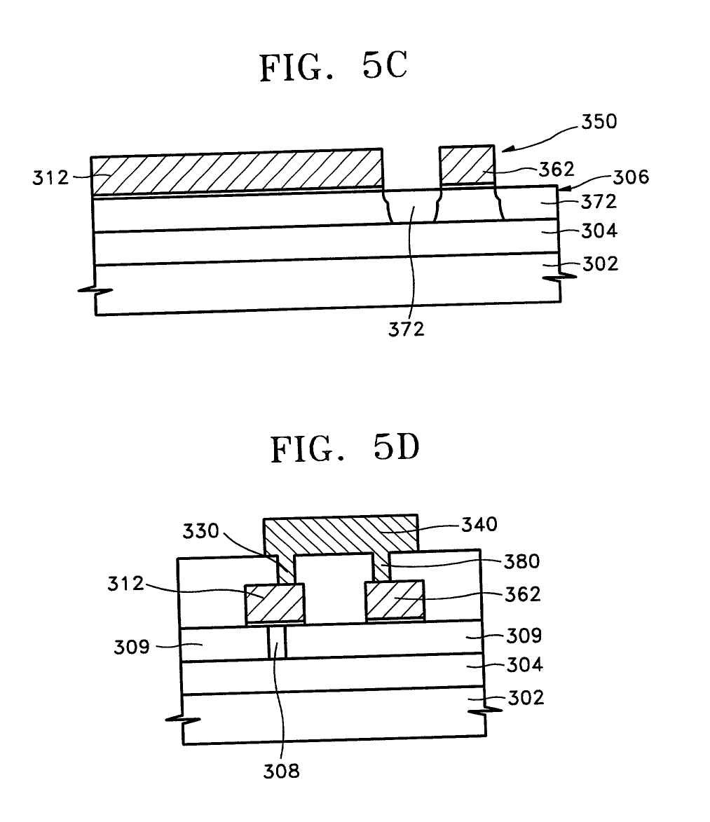

FIG. 6 is a block diagram of the semiconductor device according to another embodiment of the present invention. The semiconductor device according to the present invention includes a main complementary MOS (CMOS) circuit 410 having a main MOS transistor 412 and a main PMOS transistor 422 and an assistance CMOS circuit 420 having an assistance PMOS transistor 414 and an assistance NMOS transistor 424. The structure combining the main NMOS transistor 412 and the assistance PMOS transistor 414, and the structure combining the main PMOS transistor 422 and the assistance NMOS transistor 424, may be realized as the main MOS transistor and the assistance MOS transistor according to one of the above first through third embodiments of the present invention.

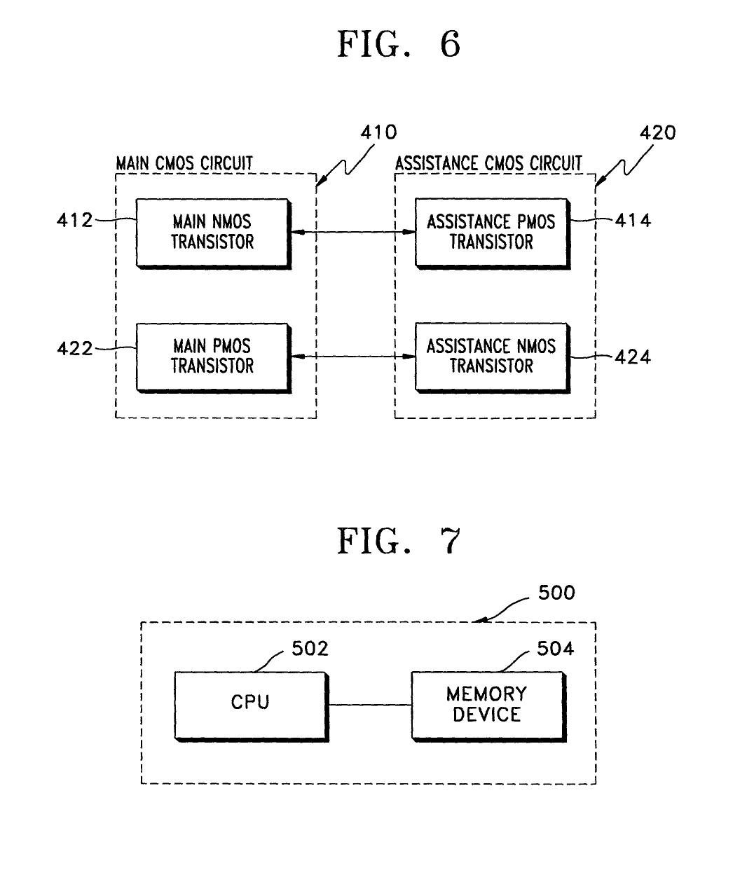

FIG. 7 is a block diagram of a signal processing system 500 according to an embodiment of the present invention. The signal processing system 500 includes a central processing unit (CPU) 502 and a memory device 504. The CPU 502 and the memory device 504 are connected by a bus. The CPU 502 and the memory device 504 may be formed of the structure combining the main MOS transistor and the assistance MOS transistor according to one of the above first through third embodiments of the present invention or the CMOS circuit having that structure.

Provided in the present invention are a semiconductor device and a signal processing system having a main MOS transistor and an assistance MOS transistor for selectively floating or grounding a body or a channel region of the main MOS transistor according to an external signal input to the main MOS transistor. The semiconductor device of the prevent invention has the structure in which the body extended from the channel region of the main MOS transistor is connected to the assistance MOS transistor, and a gate interconnection of the main MOS transistor and the gate interconnection of the assistance MOS transistor are electrically connected to each other. Thus, when the main MOS transistor is in an off state, the assistance MOS transistor is turned on, the potential of the body of the main MOS transistor is reduced by the assistance MOS transistor, the body of the main MOS transistor is grounded, and leakage current in an off state is reduced. When the main MOS transistor is in an on state, the assistance MOS transistor is turned off, and the body of the main MOS transistor is floated. Thus, junction capacitance of the channel region of the main MOS transistor is maintained at a low level, and current is increased during the operation of the main MOS transistor. The signal processing system having the semiconductor device with the above characteristics can improve operational characteristics.

While this invention has been particularly shown and described with reference to preferred embodiments thereof, it will be understood by those skilled in the art that various changes in form and details may be made therein without departing from the spirit and scope of the invention as defined by the appended claims.

1. A semiconductor device comprising:
a main metal oxide semiconductor (MOS) transistor including a first gate interconnection for receiving an external signal, first source/drain regions of a first conductivity type, and a body;
an assistance MOS transistor including a second gate interconnection and second source/drain regions of a second conductivity type, opposite to the first conductivity type, for selectively floating and grounding the body according to the external signal; and
an interconnection layer for electrically connecting the first gate interconnection and the second gate interconnection.

2. The semiconductor device according to claim 1, wherein at least part of the second source/drain regions contacts the body of the main MOS transistor.

3. The semiconductor device according to claim 1, wherein the first gate interconnection is formed of one of an H-shape gate interconnection, a T-shape gate interconnection, and an elongated gate interconnection.

4. The semiconductor device according to claim 1, wherein the main MOS transistor and the assistance MOS transistor are formed on one active region, and the plane of the active region is one of rectangular and dog-bone shaped.

5. The semiconductor device according to claim 4, further comprising an isolation region for defining the active region, wherein the interconnection layer is formed on upper portions of the first gate interconnection and the second gate interconnection that overlay region.

6. The semiconductor device according to claim 1 further comprising:
at least one first gate contact region formed on the first gate interconnection; and
at least one second gate contact region formed on the second gate interconnection;
wherein the interconnection layer is a conductive layer formed between the first gate contact region and the second gate contact region.

7. The semiconductor device according to claim 6 wherein the interconnection layer is formed of one conductive layer.

8. The semiconductor device according to claim 6, wherein the interconnection layer is formed of a plurality of conductive layers.

9. The semiconductor device according to claim 6, wherein the conductive layer is formed of one of a doped polysilicon and a metal.

10. The semiconductor device according to claim 1, wherein the interconnection layer is formed on upper portions of the first gate interconnection and the second gate interconnection that do not overlap the first source/drain regions and the second source/drain regions.

11. The semiconductor device according to claim 1, wherein the main MOS transistor further comprises a channel region formed on a lower portion of the first gate interconnection in the body, and the assistance MOS transistor is connected to the body extended from the channel region.

12. The semiconductor device according to claim 1, wherein the body is grounded by the assistance NMOS transistor when the external signal input to the main MOS transistor is at an off voltage level, and the body is floated by the assistance NMOS transistor when the external signal input to the main MOS transistor is at an on voltage level.

13. The semiconductor device according to claim 1, wherein the main MOS transistor is an NMOS transistor, and the assistance MOS transistor is a PMOS transistor.

14. The semiconductor device according to claim 1, wherein the main MOS transistor is a PMOS transistor, and the assistance MOS transistor is an NMOS transistor.

15. A semiconductor device comprising:
a main complementary MOS (CMOS) circuit comprising a first main MOS transistor and a second main MOS transistor coupled to each other in a complimentary configuration; and
at least one assistance MOS transistor for selectively floating and grounding a channel region of at least one of the first main MOS transistor and the second main MOS transistor selected according to a state of the selected main MOS transistor, the state of the main MOS transistor being one of an on state and an off state.

16. The semiconductor device according to claim 15, wherein:
the selected main MOS transistor includes a first gate interconnection for receiving an external signal, a first source/drain region, a body, and a first channel region formed in a lower portion of the first gate interconnection in the body and having a channel of a first conductivity type formed therein,
the assistance MOS transistor includes a second gate interconnection electrically connected to the first gate interconnection, a second source/drain region, and a second channel region having a channel of a second conductivity type, opposite to the first conductivity type, and
at least part of the second source/drain region contacts the body extended from the first channel region.

17. The semiconductor device according to claim 16, wherein the first gate interconnection is formed of one of an H-shape gate interconnection, a T-shape gate interconnection, and an elongated gate interconnection.

18. The semiconductor device according to claim 16, wherein the first channel region is grounded when the selected main MOS transistor is in an off state and the first channel region is floated when the selected main MOS transistor is in an on state.

19. The semiconductor device according to claim 15, wherein the selected main MOS transistor and the assistance MOS transistor are formed on one active region, and the plane of the active region is one of rectangular and dog-bone shape.

20. The semiconductor device according to claim 15, wherein the assistance MOS transistor is in an on state when the selected main MOS transistor is in an off state and the assistance MOS transistor is in an off state when the selected main MOS transistor is in an on state.

21. A signal processing system comprising:
a central processing unit (CPU);
a memory device; and
a bus for connecting the CPU to the memory device; wherein
the CPU includes a main complementary MOS (CMOS) circuit comprising a first main MOS transistor and a second main MOS transistor coupled to each other in a complimentary configuration, and at least one assistance MOS transistor for selectively floating and grounding a channel region of at least one main MOS transistor selected from the first main MOS transistor and the second main MOS transistor according to an on or off state of the selected main MOS transistor.

22. The signal processing system according to claim 21, wherein
the selected main MOS transistor includes a first gate interconnection for receiving an external signal, a first source/drain region, a body, and a first channel region formed in a lower portion of the first gate interconnection in the body and having a channel of a first conductivity type formed therein,
the assistance MOS transistor includes a second gate interconnection electrically connected to the first gate interconnection, a second source/drain region, and a second channel region having impurities of a second conductivity type, opposite to the first conductivity type, and
at least part of the second source/drain region contacts the body extended from the first channel region.

23. The signal processing system according to claim 22, wherein the first gate interconnection is formed of one of an H-shape gate interconnection, a T-shape gate interconnection, and an elongated gate interconnection.

24. The signal processing system according to claim 22, wherein the first channel region is grounded when the selected main MOS transistor is in an off state and the first channel region is floated when the selected main MOS transistor is in an on state.

25. The signal processing system according to claim 21, wherein the selected main MOS transistor and the assistance MOS transistor are formed on one active region, and the plane of the active region is one of rectangular and dog-bone shape.

26. The signal processing system according to claim 21, wherein the assistance MOS transistor is in an on state when the selected main MOS transistor is in an off state and the assistance MOS transistor is in an off state when the selected main MOS transistor is in an on state.
